(19) United States
(12) Patent Application Publication
(10) Pub. No.: US 2005/0254213 A1
(43) Pub. Date: Nov. 17, 2005

(54) Air conditioning heat dissipation system

(76) Inventors: Jack Wang, Taoyuan City (TW); Cheng-Hua Cheng, Taoyuan City (TW); Michael Lin, Taoyuan City (TW); Charles Ma, Taoyuan City (TW)

Correspondence Address: Yi-Wen Tseng, 4331 Stevens Battle Lane, Fairfax, VA, 22033, US

(21) Appl. No.: 10/843,625

(22) Filed: May 12, 2004

(51) Int. Cl. H05K 7/20

(52) U.S. Cl. 361/697

(57) ABSTRACT

An air-conditioning heat dissipation system includes a heat dissipation device and an enclosure. The heat dissipation device has a top and a bottom heat sinks secured to each other and a cryogenic chip sandwiched between the top and bottom heat sinks. The enclosure has a box assembly and a planar assembly extending from one side of the box assembly. The box assembly is operative to receive the heat dissipation device therein, and the planar assembly includes a channel having one end in communication with the box assembly and the other end open to external.

### BACKGROUND OF THE INVENTION

The present invention relates in general to an air conditioning heat dissipation system, and more particularly, to an air conditioning heat dissipation apparatus use in a host system such as a computer host. The air conditioning heat dissipation system is operative to generate cold air to reduce the temperature of the host system, so as to enhance the heat dissipation performance of the host system.

Passive devices or apparatus operative to generate heat during operation are installed in most of current host systems such as computer systems. The heat generating devices or apparatus include central processing units, power supplies, and hard drives, for example. Since the host system normally includes a housing enclosing all the heat generating devices therein, the temperature of the host system cannot hardly reduced. Therefore, heat dissipation apparatus is required to dissipate the temperature inside the host system, so as to avoid the normal operation of the passive devices and the apparatus to be affected by excessively high temperature. The heat apparatus normally includes a fan attached to a rear side of the housing to induce the ambient air into the housing, so as to reduce the temperature therein.

The above heat dissipation apparatus introduces external air into the housing of the host system, so as to reduce the temperature inside of the housing. When the room temperature (ambient temperature of the host system) is warm, the cooling effect by introducing the external air is very limited. Under such circumstance, the heat generated by the passive devices or various apparatus is accumulated within the housing. Even a plurality of fans is used for increasing the flow rate of the external air flowing into the housing, the heat dissipation effect is very limited.

To resolve the problems caused by the conventional heat dissipation apparatus as described above, with many years of experience in this field, an air conditioning heat dissipation system has been developed as described as follows.

### SUMMARY OF THE INVENTION

The present invention provides an air conditioning heat dissipation system which effectively reduces the temperature inside of a host, so as to enhance the operation stability of the host.

The present invention further provides an air condition heat dissipation system which does not generate heat inside of the host system. Instead, the heat generated by the air condition heat dissipation system is located external to the host system, such that the temperature inside the host system can be greatly reduced.

The air conditioning heat dissipation system comprises a heat dissipation device and an enclosure. The heat dissipation device includes a top and a bottom heat sinks secured to each other and a cryogenic chip sandwiched between the top and bottom heat sinks. The enclosure comprises a box assembly and a planar assembly extending from one side of the box assembly. The box assembly is operative to receive the heat dissipation device therein, and the planar assembly includes a channel having one end in communication with the box assembly and the other end open to external.

In one embodiment, the cryogenic chip comprises a cryogenic face adjacent to the bottom heat sink and a heating face adjacent to the top heat sink. The heat dissipation device further comprise a top fan mounted on top of the top heat sink and a bottom fan mounted to a bottom of the bottom heat sink. Preferably, the box assembly includes a top surface and a bottom surface perforated with a plurality of venting holes. The planar assembly includes a pair of tracks formed on two external sidewalls thereof. A holder is used for receiving the planar assembly therein. The holder is installed in a host before the planar assembly is installed therein. The holder includes a pair of tracks formed on a pair of internal sidewalls thereof. The tracks of the planar assembly are engageable with the tracks formed in the holder. The system further comprises a control device to control operation of the top and bottom fans and the cryogenic chip. The control device comprises a circuit board and a switch and a plurality of connecting interfaces formed on the circuit board.

These and other objectives of the present invention will become obvious to those of ordinary skill in the art after reading the following detailed description of preferred embodiments.

It is to be understood that both the foregoing general description and the following detailed description are exemplary and are intended to provide further explanation of the invention as claimed.

### BRIEF DESCRIPTION OF ACCOMPANIED DRAWINGS

The above objects and advantages of the present invention will be become more apparent by describing in detail exemplary embodiments thereof with reference to the attached drawings in which:

FIG. 1 illustrates a perspective view of an air conditioning heat dissipation system in one embodiment of the present invention;

FIG. 2 shows an exploded view of the heat dissipation system as shown in FIG. 1;

FIG. 3 shows a cross sectional view of the heat dissipation system as shown in FIG. 2;

FIG. 4 shows a perspective view of the heat dissipation system and a positioning frame;

FIG. 5 shows the assembly of the heat dissipation system and the positioning frame;

FIG. 6 is a perspective view of the heat dissipation system applied to a host;

FIG. 7 shows the assembly of the heat dissipation system and the host;

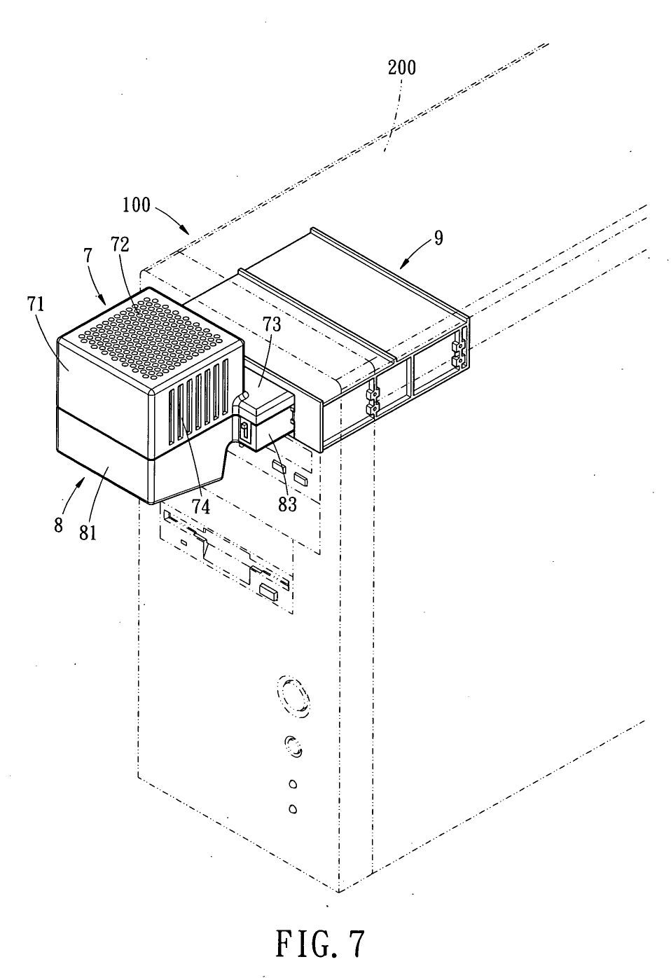

FIG. 8 shows the operation of the heat dissipation system; and

FIG. 9 is a perspective view of the heat dissipation system assembled with a host.

### DETAILED DESCRIPTION OF EMBODIMENT

Reference will now be made in detail to the preferred embodiments of the present invention, examples of which are illustrated in the accompanying drawings. Wherever possible, the same reference numbers are used in the drawings and the description to refer to the same or like parts.

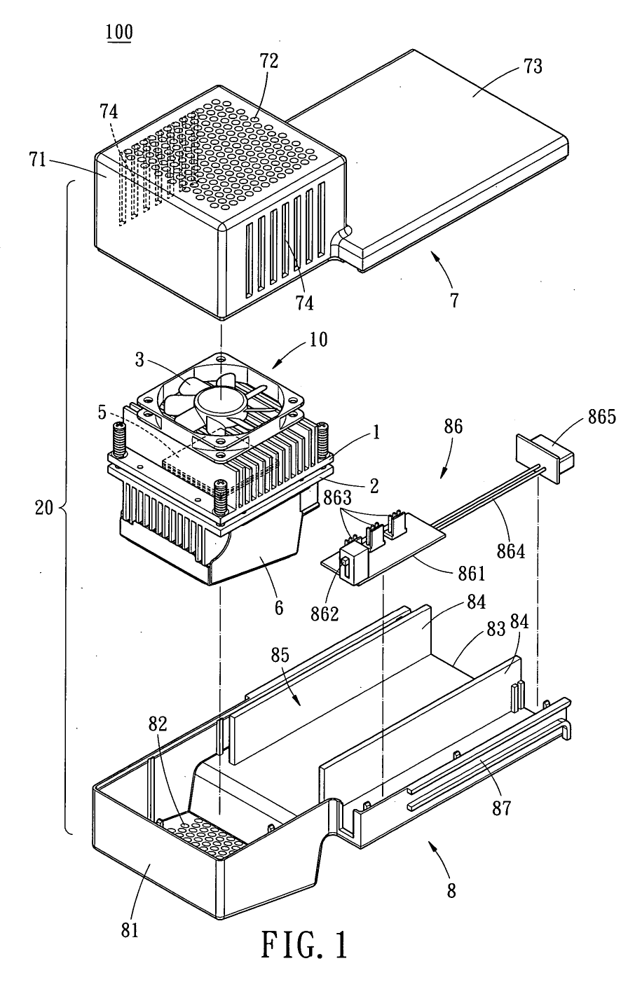

As shown in FIG. 1, the air condtioning heat dissipation system 100 includes a heat dissipation device 10 and an enclosure 20. The heat dissipation device 10 comprises a first heat sink 1 and a second heat sink 2. In this embodiment, each of the first and second heat sinks 1 and 2 comprises a substrate and a plurality of fins extending substantially perpendicularly from the substrate. The fins are fabricated from extrusion aluminum, for example. Preferably, the first heat sink 1 is stacked over a second heat sink 2 in a back-to-back fashion. That is, the substrates of the first and second heat sinks 1 and 2 are adjacent to each other. Fastening members 101 such as screws are then used to secure the substrates of the first and second heat sinks 1 and 2 together. In this embodiment, fans 3 and 4 may be mounted on to the first and second heat sinks 1 and 2, respectively. As shown, the fans 3 and 4 are mounted to the fins at the sides distal to the substrate. The rotation directions of the fans 3 and 4 can be identical to or different from each other.

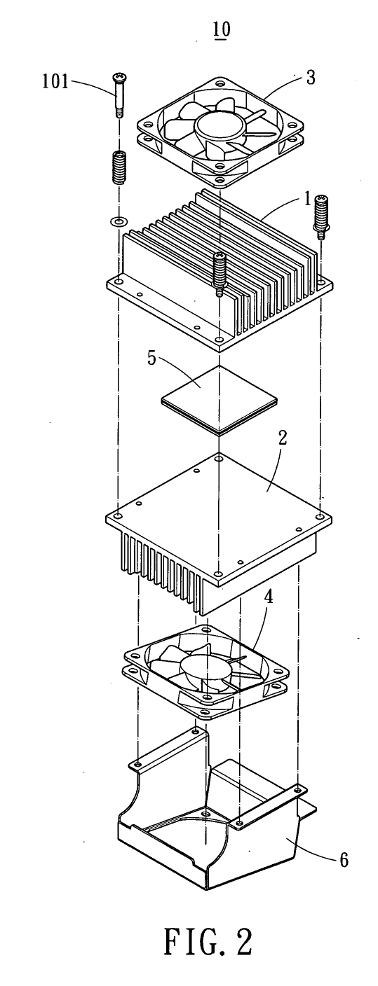

The air conditioning heat dissipation apparatus 100 further comprises a cryogenic chip 5 sandwiched between the substrates of the first and second heat sinks 1 and 2. In operation, one face of the cryogenic chip 5 serves as the cryogenic face, while the other face of the cryogenic chip 5 serves as the heating face. The ambient temperature around the heating face thus becomes higher when the cryogenic chip 5 is operating. In this embodiment, the cryogenic face of the cryogenic chip 5 is abutting the substrate of the second heat sink 2 under the first heat sink 1. In contrast, the heating face of the cryogenic chip 5 is abutting the substrate of the first heat sink 1 over the second heat sink 2. Thus assembled, a mask 6 can be used to mask the first heat sink 1 (as shown in FIGS. 1 and 2) or the second heat sink 2.

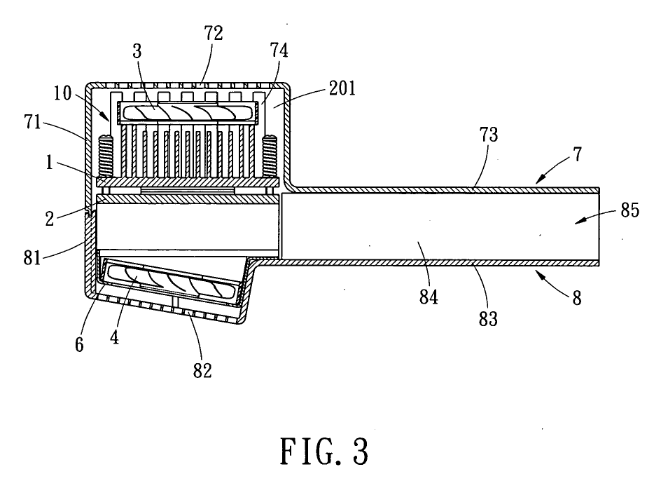

Further referring to FIG. 1, a housing 20 including a top lid 7 and bottom lid 8 is used to enclose the assembly of the first heat sink 1, the cryogenic chip 5 and the second heat sink 2. The top lid 7 comprises a rectangular box member 71 and a planar plate 73 extending from an open edge of the box member 71. Similar to the top lid 7, the bottom lid 8 also comprises a substantially rectangular box member 81 and a planar plate 83 extending from an open edge of the box member 81. The box members 71 and 81 are used to receive the first and second heat sinks 1 and 2 therein. The top and bottom surfaces of the box members 71 and 82 are perforated with a plurality of holes 72 and 82 to serve as venting holes. The planar plate 83 of the bottom lid 8 includes a pair of partitioning boards 84 extending upwardly along an elongate direction thereof. When the top lid 7 and the bottom lid 8 cover each other, a channel 85 is formed between the paritioning boards 84 and the planar plates 73 and 83. As shown in FIG. 3, the box member 74 is so dimensioned that when the first heat sink 1 is received therein, a channel 201 is formed at each lateral side of the first heat sink 1. The channel 201 is in communication with one end of the channel 85, while the other end 851 of the channel 85 is open to external. Further referring to FIG. 3, in this embodiment, the channel 85 is level with the second heat sink 2.

A control device 86 is installed in the bottom lid 8 for controlling operation of the fans 3 and 4 and the cryogenic chip 5. The control device 86 includes a circuit board 861, and a switch 862 and a plurality of connecting interfaces 863 formed on the circuit board 861. The connecting interfaces 863 provide electric communication to the fans 3 and 4 and the cryogenic chip 5. The circuit board 862 is in electric communication with a power connector 865 via a plurality of wirings 864. The power connector 865 is to be connected to a power source. In addition, tracks 87 may be formed on two external sidewalls of the planar plate 83 of the bottom lid 8, such that the assembly 10 can be mounted to the holder 9 of the host 200.

As shown in FIGS. 2 and 3, the cryogenic chip 5 is disposed between the first and second heat sinks 1 and 2 before they are secured to each other by the screw members 101. The fans 3 and 4 are then mounted to the top and the bottom of the first and the second fans 1 and 2. The fan 4 is masked by the mask 6, and second heat sink 2 is then disposed in the box member 83 of the bottom lid 8. The power cords of the fans 3 and 4 and the cryogenic chip 5 are then connected to the connection interfaces 863 of the control device 86. The top lid 7 is then mounted on the bottom lid 8 to obtain the air-conditioning heat dissipation system 100 as shown in FIG. 3.

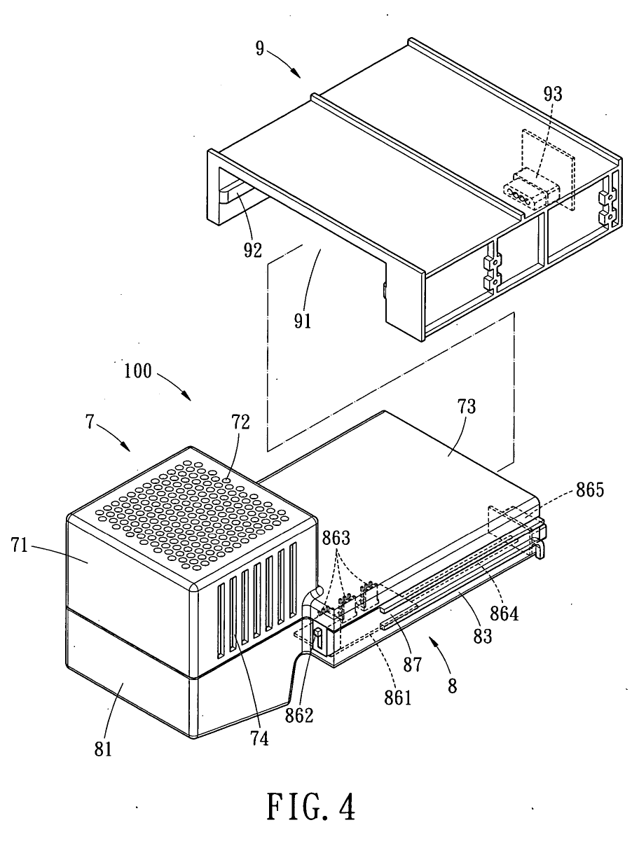

Referring to FIG. 4, a holder 9 may be used to assemble the air-conditioning heat dissipation system 100 with various types of electronic peripherals. The holder comprises a top panel and a rear panel and a pair of side panels extending downwardly from three edges of the top panel. The rear panel is disposed between to the side panels. Thereby, an assembly space 91 is formed for receiving the assembly of the planar plates 73 and 83. A pair of tracks 92 is formed at the internal sidewall of the side panels. Therefore, the assembly of the planar plates 73 and 83 can be inserted into by engaging the tracks 87 with the tracks 92. A socket 93 may be formed on the rear panel for connecting the power connector 865.

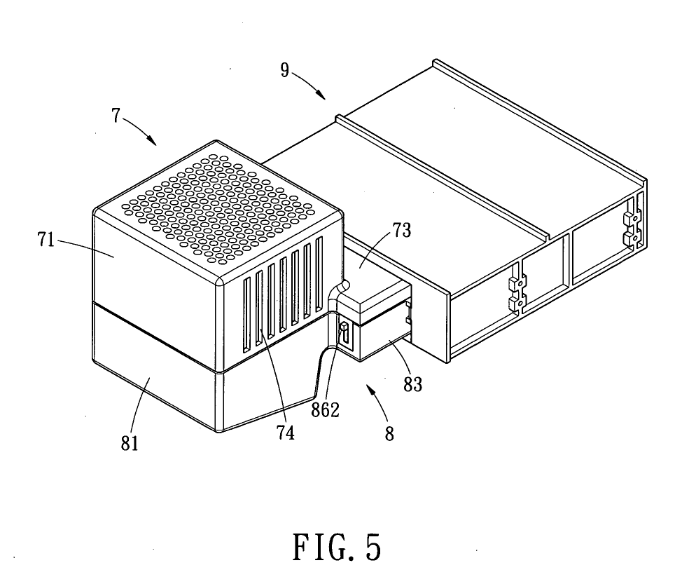

Referring to FIG. 5, to the air conditioning heat dissipation system 100 is installed in the assembly space 91 of the holder 9, the tracks 92 are aligned with the tracks 92, and the assembly of the planar plates 73 and 83 are then inserted into the assembly space 91 by sliding the tracks 87 along the tracks 92.

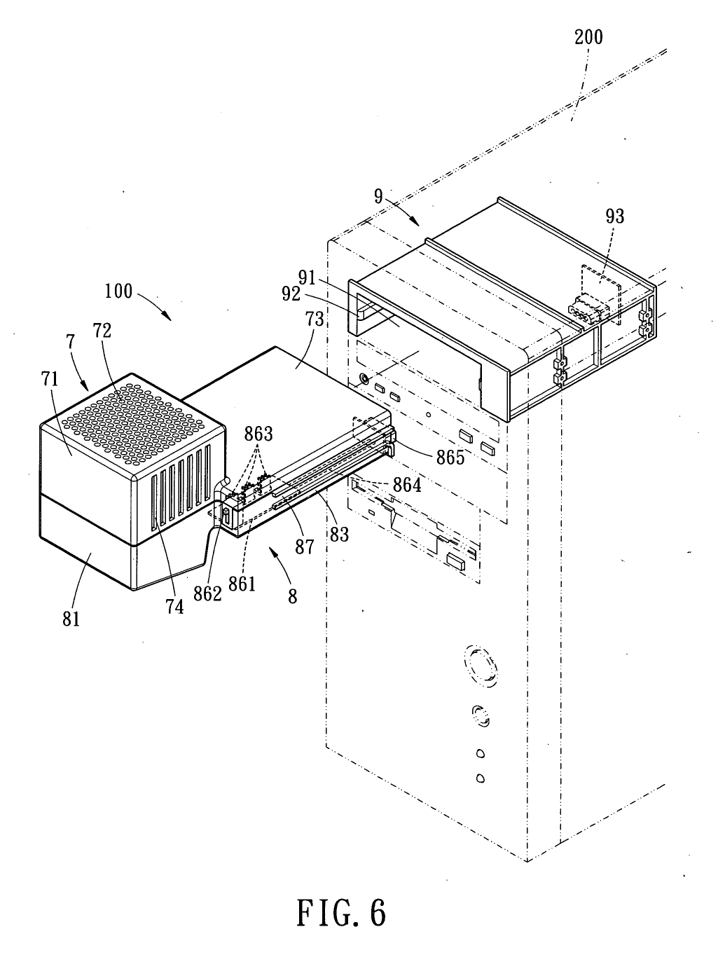

FIG. 6 illustrates the application of the air-conditioning heat dissipation system 100 in a computer host system 200. As shown, the holder 9 is installed in the host 200, and the socket 93 is connected to a power source of the computer host 200. The assembly of the planar plates of the air-conditioning heat dissipation system 100 is inserted into the holder 9, while the assembly of the first and second heat sinks 1 and 2 are disposed external to the host 200.

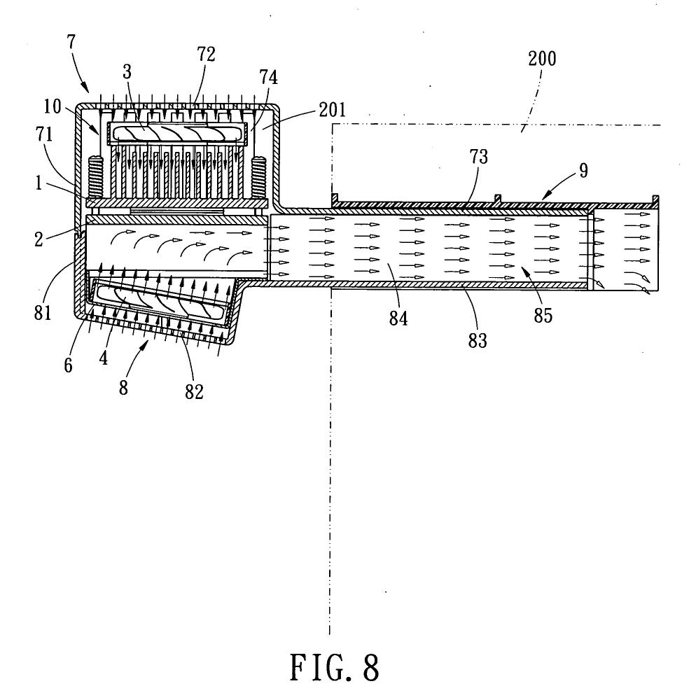

Referring to FIG. 8, in operation, the fans 3 and 4 and the cryogenic chip 5 are activated, such that external air is circulated into the enclosure 20 through the venting holes 72 and 82. As the cryogenic face of the cryogenic chip 5 is attached to the second heat sink 2, the ambient temperature around the second heat sink 2 is decreased. The external air flowing circulated by the fan 4 becomes cold air to flow into the computer host 200 through the channel 85, so as to efficiently reduce the temperature of the computer host 200.

Meanwhile, the heat generated by the cryogenic chip 5 is delivered upwardly through the heating face attached to the first heat sink 1 and the first heat sink 1. The heat is further guided out of the enclosure 20 through the venting holes 72 by the fan 3. Therefore, heat generated by the cryogenic chip 5 will not enter the host 200.

According to the above, the air-condtioning heat dissipation system 100 can efficiently reduces the temperature of the host, so as to enhance operation stability of thereof. As the heat source is disposed external to the host, and a heat dissipation mechanism is installed to effectively dissipate heat generated by the system, the heat dissipation performed is further improved.

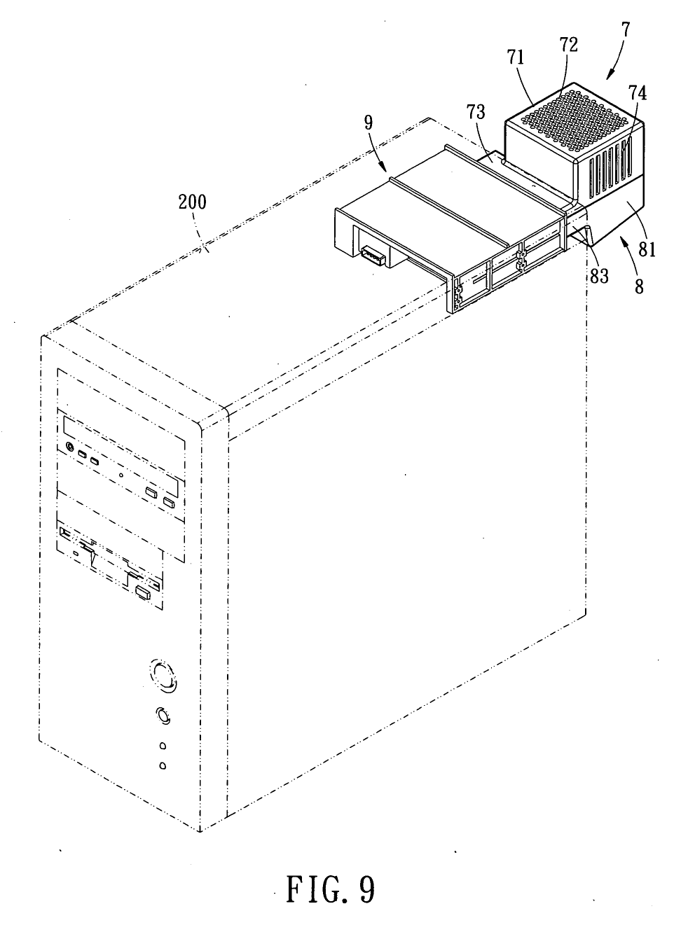

The system 100 can also be inserted to the host from a rear panel as shown in FIG. 9.

While the present invention has been particularly shown and described with reference to preferred embodiments thereof, it will be understood by those of ordinary skill in the art the various changes in form and details may be made therein without departing from the spirit and scope of the present invention as defined by the appended claims.

1. An air-conditioning heat dissipation device, comprising:
a heat dissipation device, comprising:
a top and a bottom heat sinks secured to each other; and
a cryogenic chip sandwiched between the top and bottom heat sinks; and
an enclosure, comprising a box assembly and a planar assembly extending from one side of the box assembly, wherein the box assembly is operative to receive the heat dissipation device therein, and the planar assembly includes a channel having one end in communication with the box assembly and the other end open to external.

2. The system as claimed in Chim 1, wherein the cryogenic chip comprises a cryogenic face adjacent to the bottom heat sink and a heating face adjacent to the top heat sink.

3. The system as claimed in claim 1, wherein the heat dissipation device further comprising a top fan mounted on top of the top heat sink and a bottom fan mounted to a bottom of the bottom heat sink.

4. The system as claimed in claim 1, wherein the box assembly includes a top surface and a bottom surface perforated with a plurality of venting holes.

5. The system as claimed in Clam 1, wherein the planar assembly includes a pair of tracks formed on two external sidewalls thereof.

6. The system as claimed in claim 5, further comprising a holder for receiving the planar assembly therein.

7. The system as claimed in claim 5, wherein the holder is installed in a host before the planar assembly is installed therein.

8. The system as claimed in claim 5, wherein the holder includes a pair of tracks formed on a pair of internal sidewalls thereof.

9. The system as claimed in claim 8, wherein the tracks of the planar assembly are engageable with the tracks formed in the holder.

10. The system as claimed in Chim 1, further comprising a control device to control operation of the top and bottom fans and the cryogenic chip.

11. The system as claimed in claim 1, wherein the control device comprises a circuit board and a switch aid a plurality of connecting interfaces formed on the circuit board.

12. An air-conditioning heat dissipation system for dissipating heat generated in a heat-generating host, comprising:
a heat dissipation device, comprising:
a first heat sink, having a first substrate and a plurality of first fins extending from the substrate;
a second heat sink, having a second substrate and a plurality of second fins extending from the substrate; and
a cryogenic chip, disposed between the first and second heat sinks;
at least one fastening members fastening the first and second substrates; and
a channel, in communication between the heat dissipation device and the host.

13. The system as claimed in Chim 12, wherein the heat dissipation device further comprises a fist fan mounted to the first heat sink and a second fan mounted to the second heat sink.

14. The system as claimed in claim 13, wherein the cryogenic chip comprises a cryogenic face adjacent to the first substrate and a heating face adjacent to the second substrate.

15. The system as claimed in claim 13, wherein the channel is level with the second heat sink.

16. The system as claimed in claim 13, wherein the second fan is disposed within a mask.

17. The system as claimed in claim 12, further comprising an enclosure enclosing the heat dissipation device and the channel therein.
